(19) United States
(12) Patent Application Publication
(10) Pub. No.: US 2026/0203477 A1
(43) Pub. Date: Jul. 16, 2026

(54) PASSIVE STRUCTURE DESIGNS FOR PHASED ANTENNA ARRAYS

(71) Applicant: 3M INNOVATIVE PROPERTIES COMPANY, St. Paul, MN (US)

(72) Inventors: Milo G. Oien-Rochat, Minneapolis, MN (US); Zohaib Hameed, Woodbury, MN (US); Nader Tavaf, Minneapolis, MN (US); lan Cummings, Brookfield, WI (US); Jaewon Kim, Woodbury, MN (US); Marcus Schwarting, Bolingbrook, IL (US); Elias Wilken-Resman, Minneapolis, MN (US); Charles L. Bruzzone, Woodbury, MN (US); Jennifer J. Sokol, Mahtomedi, MN (US); Karthik Subramanian, St. Paul, MN (US)

(21) Appl. No.: 19/132,736

(22) PCT Filed: Nov. 30, 2023
(86) PCT No.: PCT/IB2023/062102

§ 371 Date: May 23, 2025

Related U.S. Application Data
(60) Provisional application No. 63/430,262, filed on Dec. 5, 2022.

(51) Int. Cl. G06F 30/27; G06N 3/0455

(52) U.S. Cl. CPC G06F 30/27; G06N 3/0455

(57) ABSTRACT

A method of generating a passive structure design includes receiving, by processing circuitry of a computing device, a set of performance metrics; providing, by the processing circuitry, the set of performance metrics to a trained generator network; receiving, by the processing circuitry, a passive structure design from the generator network; and outputting, by the processing circuitry, via a communication interface, the passive structure design.

### TECHNICAL FIELD

This disclosure relates to systems and techniques for designing passive structures to be used in phased antenna arrays.

### SUMMARY

As part of upgrading the current mobile network infrastructure to provide 5G voice and data services, millimeter wave (mmWave) phased-array antennas are being installed on the existing radio access network (RAN) cell sites. As used herein, 5G refers to voice and data services that comply with the fifth-generation technology standard for broadband cellular networks. Each such site typically supports three sector antenna arrays, with each antenna array providing 120° (i.e. +/−) 60° azimuthal coverage within a given cell. Combined, the three sector antennas provide 360° omnidirectional coverage around the site. Prevalent 4G/LTE systems work on frequencies below 6 GHZ, which have low propagation losses in comparison to mmWave frequencies, which are generally at or above 20 GHz. To provide the network coverage at the same range (distance from the RAN cell site) as prevalent 4G/LTE systems, mmWave antennas must (i) be highly directive, and (ii) have steerable radiation patterns. Antenna arrays, which include multiple radiating elements provide these enhancements in the context of mmWave equipment. Antenna arrays generally provide spatial diversity (a facet by which a base station can communicate with multiple devices within the same cell using the same time-frequency resource with the help of highly directive antennas) using massive multiple-input, multiple-output (massive-MIMO) architectures as in the case of 5G system specifications.

High directivity, however, introduces one or more diminishments. Providing high directivity requires many elements in each phased array, and limits the azimuthal scan range of the overall antenna system due to beam broadening as the phased array broadcasts further from the optical axis referred to as “antenna boresight.” As such, mmWave phased arrays, being highly directional, cannot provide 120° coverage without introducing significant gain degradation at wider scan angles. This gain degradation leads to decreased coverage at the sector seams within a communication cell.

Techniques of this disclosure are directed to designing passive structures (e.g., dielectric lenses) that broaden the scan range of mmWave phased antenna arrays. A potential advantage provided by the passive structure designs (e.g. dielectric lens designs) of this disclosure relates to obtaining a narrower beamwidth. For example, a lower order array (e.g., an array with a lesser number of antenna elements) incorporating the passive structure designs of this disclosure can provide resolutions similar to a higher order array (e.g., an array with a greater number of antenna elements).

In one example, a system includes interface hardware, a memory communicatively coupled to the interface hardware, and processing circuitry communicatively coupled to the memory and the interface hardware. The memory is configured to store a set of performance metrics. The processing circuitry is configured to provide the set of performance metrics to a trained generator network, and receive, from the trained generator network, a passive structure design. The interface hardware configured to output the passive structure design.

In another example, a method includes receiving, by processing circuitry of a computing device, a set of performance metrics, and providing, by the processing circuitry, the set of performance metrics to a trained generator network. The method further includes receiving, by the processing circuitry, a passive structure design from the generator network, and outputting, by the processing circuitry, via a communication interface, the passive structure design.

In another example, an apparatus includes means for receiving a set of performance metrics, means for providing the set of performance metrics to a trained generator network, means for receiving a passive structure design from the generator network, and means for outputting via a communication interface, the passive structure design.

In another example, a non-transitory computer-readable storage medium is encoded with instructions. The instructions, when executed by one or more processors, cause the one or more processors to receive a set of performance metrics, to provide the set of performance metrics to a trained generator network, to receive a passive structure design from the generator network, and to output the passive structure design via an interface.

In another example, a method of training a generator network includes receiving a set of training pairs, each training pair comprising a training passive structure and performance data associated with the training passive structure. The method further includes, for each training pair included in the set of training pairs: providing the corresponding performance data to the generator network, receiving an artificial passive structure from the generator network, providing the artificial passive structure and the passive structure included in the training pair to a discriminator network, receiving a score from the discriminator network, and updating, based on the score, the discriminator network and the generator network to form, respectively, a trained discriminator network and a trained generator network. The method further includes outputting the trained generator network.

In another example, a system includes interface hardware, a memory communicatively coupled to the interface hardware, and processing circuitry communicatively coupled to the memory and the interface hardware. The memory is configured to store a set of training pairs, each training pair comprising a training passive structure and performance data associated with the training passive structure. The processing circuitry is configured to, for each training pair included in the set of training pairs: provide the corresponding performance data to the generator network, receive an artificial passive structure from the generator network, provide the artificial passive structure and the passive structure included in the training pair to a discriminator network, receive a score from the discriminator network, and update, based on the score, the discriminator network and the generator network to form, respectively, a trained discriminator network and a trained generator network. The interface hardware configured to output the trained generator network.

The passive structure design techniques of this disclosure provide several technical improvements in the technical field of phased antenna array design. In this way, the passive structure designs of this disclosure may reduce the design complexity and cost of the phased antenna array systems by reducing the number of one or more of phase-shifters, amplifiers, and/or impedance-matching networks required in the system. Passive structures designed according to the techniques of this disclosure provide these performance enhancements in the context of three-sector antenna implementations, but in many cases, can reduce the infrastructure to one-antenna or two-antenna arrays, particularly in use cases that cover a smaller, more densely device-deployed area, such as an urban downtown area. Moreover, the improvements provided by passive structures designed according to the techniques of this disclosure improve performance and capacity at the cell level, thereby potentially reducing the number of arrays required from a higher (e.g., system-level) perspective.

### BRIEF DESCRIPTION OF DRAWINGS

FIGS. 1A & 1B illustrate differences between the signal coverage provided by an existing phased antenna array and the enhanced signal coverage of a corresponding phased antenna array that is equipped with passive structures designed according to the techniques of this disclosure.

FIG. 2 is a flowchart illustrating an example workflow of this disclosure.

FIG. 3 is a block diagram illustrating an example implementation of a passive structure generation device of this disclosure.

FIGS. 4A & 4B illustrate a three-dimensional representation and a two-dimensional representation, respectively, of a dielectric lens generated by a generative adversarial network (GAN)-based implementation of a trained model of this disclosure when run in an execution phase.

FIG. 5 is a graph illustrating the gain values provided by a phased antenna array that incorporates dielectric lenses that conform to the GAN-generated designs shown in FIGS. 4A & 4B.

FIGS. 6A & 6B illustrate a three-dimensional representation and a two-dimensional representation, respectively, of a dielectric lens generated by a GAN-based implementation of a trained model of this disclosure when run in an execution phase.

FIG. 7 is a graph illustrating the gain values provided by a phased antenna array that incorporates dielectric lenses that conform to the GAN-generated designs shown in FIGS. 6A & 6B.

FIG. 8 is a graph showing the increase in peak gain (or max gain) provided by phased antenna arrays equipped with the inverse-designed dielectric lenses of this disclosure in comparison to the peak gain provided by other phased antenna arrays.

FIG. 9 is a graph comparing the increase in peak gain (or max gain) provided by phased antenna arrays equipped with modified and unmodified versions of the inverse-designed dielectric lenses of this disclosure and by a phased antenna array that is not augmented with any dielectric lens infrastructure.

FIG. 10 is a block diagram illustrating aspects of a training phase with respect to the training model of FIG. 3.

FIG. 11 is a block diagram illustrating an example of an autoencoder neural network (ANN)-based architecture of the training model and the trained model of FIG. 3.

FIG. 12 illustrates examples of dielectric lens designs generated by an ANN-based implementation of the trained model of FIG. 3.

FIG. 13 illustrates top-level views of examples of dielectric lens designs generated by an ANN-based implementation of the trained model of FIG. 3.

FIG. 14A is a scatterplot that clusters fully encoded instances of a latent space representation for various lens designs. FIG. 14B is a conceptual diagram illustrating top views of a selection of lens designs represented in FIG. 14A.

FIG. 15 illustrates results of GAN-based inverse design optimization techniques of this disclosure.

FIG. 16 illustrates an example of interpolated lens designs generated as part of the labeled dataset generation techniques of this disclosure.

### DETAILED DESCRIPTION

Systems of this disclosure address various performance pitfalls of existing 4G/LTE antenna arrays when repurposed for 5G voice and data service delivery. Passive structures (e.g., dielectric lenses) designed according to the techniques of this disclosure, when incorporated into phased antenna arrays, improve signal coverage. For example, the passive structures designed according to the techniques described herein may enable the phased antenna arrays to maintain a non-increasing beamwidth even as the azimuthal angle increases.

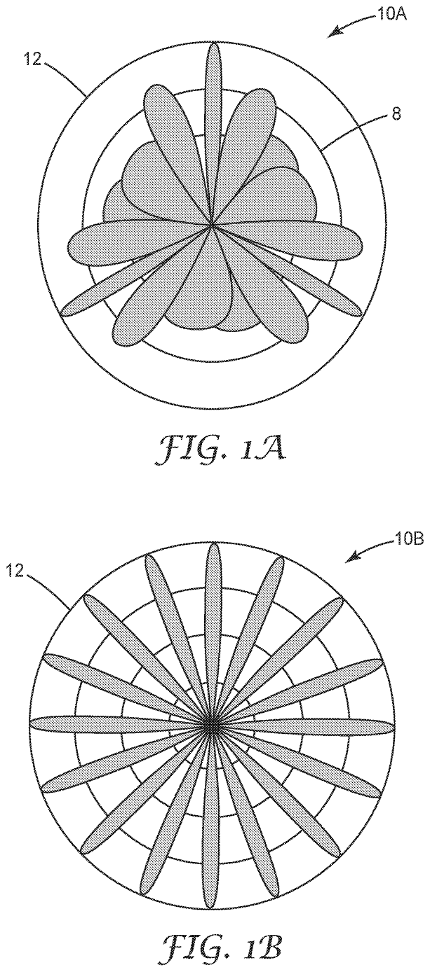

FIGS. 1A & 1B illustrate differences between the signal coverage provided by an existing phased antenna array and the enhanced signal coverage of a corresponding phased antenna array that is equipped with passive structures designed according to the techniques of this disclosure. FIG. 1A illustrates signal coverage provided by a three-sector antenna array that is equipped with currently available passive structures (e.g., dielectric lenses). System 10A of FIG. 1A provides three instances of radio frequency (RF) beams at boresight angles (i.e. zero degrees from the respective antenna of the three-sector array), equally spaced at 120 degrees from one another, that reach cellular boundary 12. FIG. 1A illustrates signal blind zone 14, which is a non-limiting example of signal coverage gaps (or so-called “dead spots”). While system 10A includes two other of signal coverage gap in addition to signal blind zone 14. The radio frequency (RF) beams in these areas of signal coverage gap exhibit widened beamwidth in proportion to the corresponding azimuthal angles. The wider beamwidths associated with these RF beams diminishes the corresponding beam depths, thereby causing signal coverage diminishments or dead zones before reaching the perimeter represented by cellular boundary 12.

FIG. 1B illustrates signal coverage provided by a three-sector antenna array that is equipped with passive structures (e.g., dielectric lenses) that are designed according to the techniques of this disclosure. All sixteen RF beams of system 10B of FIG. 1B reach cellular boundary 12, because the beamwidths of the beams do not increase with the azimuthal angle and the gain is uniform with the azimuthal angle. The radiation patterns of the boresights provide signal coverage throughout the 360-degree sweep of system 10B, as shown by way of the non-limiting example of signal coverage zones 16.

In this way, passive structures (e.g., dielectric lenses) designed according to the techniques of this disclosure enable full-cell site signal coverage, even when retrofitted into existing three-sector antenna array infrastructures. The full-cell signal coverage provided by system 10B is realized through passive structures that are designed through inverse design techniques of this disclosure. The inverse design techniques of this disclosure take, as input, one or more performance metrics. The performance metrics may represent any of a minimum performance standard for a planned phased antenna array, a maximum possible performance for the planned phased antenna array, an average thereof, or any other planned performance standard. In one non-limiting example, one or more facets of the signal coverage shown in system 10B of FIG. 1B may be represented in the performance metrics.

The performance metrics may include, be, or be part of training phase inputs, of execution phase inputs, or both. In various examples consistent with this disclosure, the performance metrics may be included in input data provided to a machine learning (ML) model or artificial intelligence (AI) model. In a training phase of the AI/ML model, systems of this disclosure may train the AI/ML model by providing a set of performance metrics as training data. In an execution phase of the trained AI/ML model, a device may provide a set of performance metrics to the trained AI/ML model as an execution phase input. Whether in the training phase or in the execution phase, the AI/ML model may return, as output, a passive structure design. In various non-limiting examples, the AI/ML model may return a passive structure design that represents a planned structure of a dielectric lens, a planned structure of an irregularly shaped lens, etc.

Various AI/ML model architectures can be used in accordance with the automated design techniques of this disclosure. For example, various types of neural networks are compatible with the automated design techniques of this disclosure. In some examples, the trained AI/ML model may represent a generator network that was trained as part of a generative adversarial network (GAN) that incorporates the use of a complementing discriminator network in the training phase. In various examples of GAN-based implementations of the techniques of this disclosure, the generator network and the discriminator network are included in at least one of a deep convolutional generational adversarial network (DCGAN), a Wasserstein generational adversarial network (Wasserstein GAN), a PixelGAN, or a CycleGAN. In some examples, the trained generator may be an autoencoder model. One example of an autoencoder model that can be used in accordance with the inverse design techniques of this disclosure is a variational autoencoder (VAE).

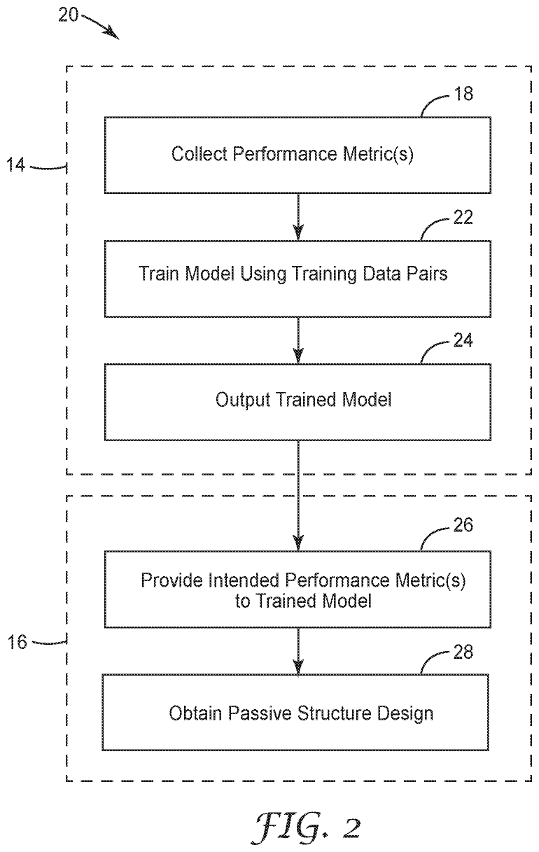

FIG. 2 is a flowchart illustrating an example workflow 20 of this disclosure. Workflow 20 includes a training phase 14 and an execution phase 16. It will be appreciated that workflow 20 can be implemented locally on a single system, or in a distributed way, over disparate systems. In a distributed implementation, training phase 14 may be implemented by a first computing system, and a trained model that that is the output of training phase 14 may be put into execution phase 16 by a second computing system that is different from the first computing system. While execution phase 16 is shown by way of a single instance in FIG. 2 for ease of illustration, it will be appreciated that execution phase 16 may be implemented in multiple instances. For example, multiple instances of the trained model output by training phase 14 may be deployed across multiple computing systems, thereby enabling the multiple computing systems to individually generate passive structure designs as needed, while leveraging the inverse design techniques of this disclosure in each instance.

Training phase 14 of workflow 20 may begin with the collection of one or more performance metrics (18). For example, a training system of this disclosure may collect performance metrics for lenses of various shapes, form factors, etc., with the performance metrics indicating facets of a phased antenna array that is equipped with lenses of each type (shape and/or form factor). The training system may maintain a respective one-to-one mapping between respective performance data (e.g., a single performance metric or a discrete grouping of performance metrics) and the lens type from which the respective performance data is obtained (the latter is also referred to as a “training passive structure” herein).

The training system may train an AI/ML model using the training data pairs (22). In an example in which the model conforms to a GAN architecture, the training system may, on a training pair by training pair basis, provide the corresponding performance data to the generator network of the GAN, and receive, as output, an artificial passive structure from the generator network. In turn, the training system may provide a combination of the passive structure (that was included in the training pair) and the artificial passive structure (that was output by the generator network) to a discriminator network that complements the generator network in the GAN architecture. The training system may receive a score from the discriminator network. Using the score returned by the discriminator network, the training system may update the generator network and the discriminator network. The training system may iterate the above-described training operations for the generator network and the discriminator network of the GAN until the training system determines that the generator network has achieved convergence.

Training phase 14 of workflow 20 may conclude with the training system outputting the trained AI/ML model (24). In the GAN-based example described above, the training system may discard the trained discriminator network and output only the trained generator network. As described above, based on need, the training system may output one instance or multiple instances of the trained generator network. In this way, training phase 14 of workflow 20 supports scalability by providing the capability to deploy the trained generator network to a potentially large number of systems (hereinafter, “utilization systems”) that can execute the trained generator network by providing desired performance metric(s) as an input to generate passive structure designs to be used in phased antenna array construction. In some use case scenarios, the training system may also be one of the utilization systems that executes the trained model.

Execution phase 16 of workflow 20 may be implemented by any one or more of the utilization systems to which the trained model is deployed, as described above with respect to the conclusion of training phase 14. Execution phase 16 may begin with a respective utilization system providing one or more intended performance metrics to the trained model (26). The intended performance metrics may represent one or more of a gain value (e.g., a maximum gain that generally corresponds to beam depth), beam width (e.g., a half power beam width), etc. In some examples, each of the intended performance metrics that is provided as an execution phase input is associated with a corresponding scan angle. For instance, each scan angle may represent an increment in the azimuthal angle using the boresight axis as the baseline.

The utilization system may obtain, as output from the trained model, a passive structure design (28). In various examples consistent with this disclosure, the passive structure design returned by the trained model at the conclusion of execution phase 16 may represent the shape of a dielectric lens to be used in a phased antenna array. Because the trained model of this disclosure takes performance metric(s) as an input in execution phase 16 and outputs a dielectric lens design, the techniques implemented by the trained model of this disclosure are referred to as “inverse design” with respect to dielectric lenses or other passive structures.

Results of experiments conducted using the passive structure designs of this disclosure, as well as the technical improvements that were observed from the experimental results, are described below. Dielectric lenses manufactured in conformance with a passive structure design output by a trained model of this disclosure were fitted to a 4×4 antenna array to validate the design. A 4×4 antenna array typically provides 60-degree (i.e., +/−30-degree) azimuthal coverage, while an 8×8 antenna array typically provides 120-degree (i.e., +/−60-degree) azimuthal coverage. The dielectric lenses manufactured in accordance with an inverse design spec generated by the trained model of this disclosure was validated using a 4×4 antenna array rather than an 8×8 antenna array for a number of reasons, some of which are described below.

As one example, individual antenna elements (e.g., amplitude and/or phase) are more easily controlled in a 4×4 antenna array in comparison to an 8×8 antenna array. The incorporation of an external lens structure makes it more important to have control over individual antenna elements to control the scan angles. As another example, execution phase 16 runs faster (sometimes by a factor of seven) with respect to passive structure design for a 4×4 than for an 8×8 array, and a dielectric lens design generated for a 4×4 antenna array can be extrapolated to an 8×8 antenna array relatively easily. Because the goal of the experiments is to validate the lens concept via model and measurement, this type of extrapolation is viable. The number of iterations required with respect to training phase 14 as well as execution phase 16 are reduced significantly for a 4×4 antenna array scenario as opposed to an 8×8 antenna array scenario. The trained model can generate an inverse design for a dielectric lens in a matter of seconds in some scenarios.

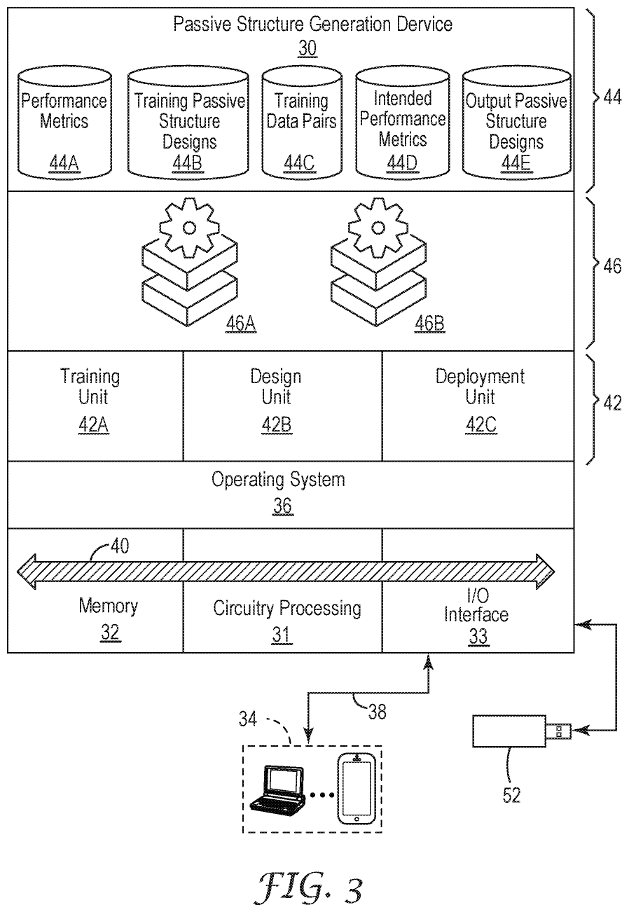

FIG. 3 is a block diagram illustrating an example implementation of a passive structure generation device 30 of this disclosure. While FIG. 3 shows one implementation of passive structure generation device 30 that is consistent with aspects of this disclosure, it will be appreciated that other architectures (whether single-device architectures or distributed architectures) of the functionalities described with respect to passive structure generation device 30 are consistent with aspects of this disclosure, as well. In the particular example of FIG. 3, passive structure generation device 30 performs functionalities of both a training system (that performs training phase 14 of FIG. 2) and a utilization system (that performs execution phase 16 of FIG. 2). In other examples consistent with this disclosure, systems may be configured to perform either exclusively as a training system, or exclusively as a utilization system. As such, it will be appreciated that different configurations are consistent with the techniques of this disclosure, and that FIG. 3 illustrates one non-limiting example of a system configuration consistent with this disclosure.

In the example of FIG. 3, passive structure generation device 30 includes processing circuitry 31 and memory 32. In some examples, processing circuitry 31 and memory 32 may be integrated into a single hardware unit, such as a system on a chip (SoC) or integrated circuit (IC). Processing circuitry 31 may represent one or more processors or processing units, each of which may comprise one or more of a multi-core processor, a controller, a digital signal processor (DSP), an application specific integrated circuit (ASIC), a field-programmable gate array (FPGA), processing circuitry (e.g., fixed function circuitry, programmable circuitry, or any combination of fixed function circuitry and programmable circuitry) or equivalent discrete logic circuitry or integrated logic circuitry. Memory 32 may include any form of memory for storing data and executable software instructions, such as random-access memory (RAM), read-only memory (ROM), programmable read only memory (PROM), erasable programmable read-only memory (EPROM), electronically erasable programmable read only memory (EEPROM), and flash memory. Memory 32 may include a single memory unit or multiple memory units in various implementations.

Memory 32 and processing circuitry 31, in combination, provide a computing platform for executing operating system 24. Operating system 24 provides a multitasking operating environment for executing one or more software components 42. As shown, processing circuitry 31 connects via an input/output (I/O) interface 33 to external systems and devices, e.g., via one or more communication networks. I/O interface 33 may incorporate network interface hardware, such as one or more wired and/or wireless network interface controllers (NICs) for communicating via communications link 38.

In the particular example of FIG. 3, communications link 38 represents one or more network-enabled communicative connections, such as a link to one or more packet-switched networks collectively referred to in the context of FIG. 3 as a “communicative network.” The communicative network may represent any of a data-enabled telephony network (such as a cellular data network), a wide-area network (such as the Internet), a public network (such as the Internet), a private network such as a local-area network (LAN) and/or an enterprise network, or any other type of network that enables data communications, or any combination of any two or more of the networks listed above.

Communications link 38 communicatively couples passive structure generation device 30 to the communicative network, and via the communicative network, to other devices. Each of communications links 38 may include one or more wired connections (e.g., an Ethernet® connection), wireless connections (e.g., a Wi-Fi™ connection) or a combination of both wired and wireless communicative connections. In the example illustrated in FIG. 3, I/O interface 33 also facilitates communication between passive structure generation device 30 and one or more remote devices 34 via communications link 38. In the particular example of FIG. 3, communications link 38 represents one or more local connections, such as a connection to remote devices 34 via a local area network (LAN) and/or personal area network (PAN) connections, such as one or more of near-field communication (NFC) pairings, Bluetooth® pairings, Zigbee® pairings, or the like. Remote devices 34 may include any one or more of computing devices (e.g., devices deployed at dielectric lens manufacturing entities), additive manufacturing devices (e.g., so-called “3D printers”), or the like.

Bus 40 provides inter-component connectivity between processing circuitry 31, memory 32, and I/O interface 33 in the implementation shown in FIG. 3. Bus 40 may represent a half-duplex or full-duplex bus that provides data transfer capabilities between two or more of processing circuitry 31, memory 32, I/O interface 33, and/or any other hardware components of passive structure generation device 30. Bus 40 may represent a system bus or a computer bus of various types, including one or more bus networks. Regardless of the topology implemented, bus 40 may, in various examples, incorporate various types of inter-component connectivity hardware such as those conforming to any of first generation, second generation, third generation, or fourth generation bus or bus network technology as set forth by the Institute of Electrical and Electronics Engineers (IEEE), and/or other bus or bus network technologies defined in developing or later-adopted standards.

Software components 42 of passive structure generation device 30, in the particular example of FIG. 3, include training unit 42A, design unit 42B, and deployment unit 42C. In some example approaches, one or more of software components 42 represent executable software instructions that may take the form of one or more software applications, software packages, software libraries, hardware drivers, and/or Application Program Interfaces (APIs). Moreover, any of software components 42 may, when executed, cause passive structure generation device 30 to output data and/or receive data via I/O interface 33.

Aspects of memory 32 that provide non-volatile storage and/or long-term storage support the local storage of data repositories 44 at passive structure generation device 30. In the example of FIG. 3, data repositories 44 include performance metrics 44A, training passive structure designs 44B, training data pairs 44C, intended performance metrics 44D, and output passive structure designs 44E. One or more of software components 42 may invoke processing circuitry 31 and memory 32 to access one or more of data repositories 44 to retrieve data for various purposes, such as for model training, trained model deployment, trained model execution, or passive structure design deployment.

In some examples, software components 42 may implement read/write capabilities with respect to data repositories 44, such as to access and use information available from data repositories 44 and/or to modify information currently stored to data repositories 44. In implementations in which passive structure generation device 30 represents a distributed computing system, one or more of data repositories 44 may be partially or entirely positioned at a remote location from processing circuitry 31, and software components 42 may, in these implementations, access data repositories 44 using NIC hardware of I/O interface 33.

Passive structure generation device 30 may obtain performance metrics 44A and/or training passive structure designs 44B from one or more sources, such as from remote devices 34, by way of direct user input entered using one or more input devices coupled to passive structure generation device 30 via I/O interface 33, etc. Training passive structure designs 44B may include one or both of designs representing dielectric lenses that have been used in the field or in experimental settings, and/or prospective designs representing dielectric lenses that have not yet been manufactured or prototyped. Performance metrics 44A may include performance-indicating data collected from experiments that were conducted using dielectric lens of one or more configurations.

In some examples, performance metrics 44A may include simulation-generated performance indicators for dielectric lens designs for which performance is modeled via a simulator or simulation technique. Non-limiting examples of performance metrics 44A include values such as gain, beam width (which may, in some instances be specified as a “half power beam width”), a maximum gain (which is an indicator of beam depth), etc. In various use-case scenarios consistent with aspects of this disclosure, each data point included in performance metrics 44A may be matched to a particular scan angle at which the respective performance metric was observed or simulated.

In various experiments, performance metrics 44A were populated with finite difference time domain simulations performed using a 3D electromagnetic (EM) analysis software suite, with each respective simulation featuring a different dielectric lens placed over a 4×4 element patch array that is modeled after a commercially available 28 GHz array. The candidate dielectric lenses were subject to specific size constraints and were specified as having a dielectric constant (ϵr) value of 1.5, with a loss tangent of 0.0032. In some instances, in addition to the fully simulated datapoints obtained in this way, passive structure generation device 30 may augment performance metrics 44A using autoencoder-generated datapoints.

For example, passive structure generation device 30 may execute an autoencoder that is trained via learning mechanisms to encode dielectric lens designs into a latent space embedding. Passive structure generation device 30 may then interpolate the latent space embedding to generate various dielectric lens shapes. Empirical observations indicate that the combined performance of the offspring lens (i.e., the dielectric lens design obtained from interpolating two given parent lenses) is relatively close to the interpolated performance of the parent lenses.

In some examples, passive structure generation device 30 may leverage various technical enhancements provided by variational autoencoders. Passive structure generation device 30 may use a variational autoencoder to generate the dielectric lens shapes of training passive structure designs 44B. For instance, passive structure generation device 30 may avail of the combination of data precision and dimensionality reduction capabilities provided by variational autoencoders. By availing of the scalability provided by the latent space dimensionality reduction provided by the encoder side of a variational autoencoder and the low-loss reconstruction provided by the decoder side of a variational autoencoder to deliver performance-accurate dielectric lens designs to training passive structure designs 44B in a computationally lightweight manner.

Passive structure generation device 30 may invoke training unit 42A to form training data pairs 44C. For instance, training unit 42A may match each respective scan angle-specific metric of performance metrics 44A to a corresponding predetermined dielectric lens design of training passive structure designs 44B to form a respective two-tuple of training data pairs 44C. In a simulation-driven example, training unit 42A may pair an autoencoder (e.g., variational autoencoder) generated dielectric lens design to a 3D EM analysis software-generated performance metric to form a respective two-tuple of training data pairs 44C. Each two-tuple of training data pairs 44C may be represented generally in following format: {engineered design, performance}.

In the implementation illustrated in FIG. 3, passive structure generation device 30 includes AI/ML models 46. AI/ML models 46 include a training model 46A and a trained model 46B. Training unit 42A may use training data pairs 44C as training data to train training model 46A. That is, training unit 42A may train training model 46A provide various two-tuples of training data pairs 44B as training data to training model 46A during training phase 14. Each two-tuple of training data pairs 44B may include a single entry (representing a dielectric lens design) from training passive structure designs 44B and corresponding performance data, which may represent one or more datapoints in performance metrics 44A. Each of the training data pairs 44C that training unit 42A provides to training model 46A is associated with a corresponding scan angle at which the performance data reflects the performance delivered by the corresponding dielectric lens when integrated into a phased antenna array. In some examples, passive structure generation device 30 (and/or other system(s) configured to perform techniques of this disclosure) may generate each tuple of training passive structure designs 44B using a Bayesian technique.

According to some implementations of the techniques of this disclosure, training model 46A represents a neural network, such as an autoencoder neural network (ANN). The techniques of this disclosure incorporate optimization into ANNs via derivation of latent space representations while also availing of the interpolative and extrapolative design capabilities provided by ANNs. The techniques of this disclosure leverage optimization methods with target reward functions for directed design experimentation as part of the inverse generative design functionalities described herein. In instances in which training model 46A represents an ANN, training model 46A includes two neural networks, namely, an encoder network and a decoder network. The encoder network and the decoder network of the ANN leverage dimensionality reduction capabilities that enable the two networks to operate on reduced-dimension vector representation known as a “latent space representation.” While the techniques of this disclosure are described with respect to the use case of EM device design, it will be appreciated that the optimization-enhanced ANN application techniques of this disclosure can be applied to other end use applications as well.

According to some implementations of the techniques of this disclosure, training model 46A represents an artificial neural network, such as a variational autoencoder (VAE) network. In VAE-based implementations, the techniques of this disclosure leverage the significant encoder-side dimensionality reduction in latent space representation formation and the low-loss (or potentially even lossless) decoder-side reconstruction. In this way, in VAE-based implementations, passive structure generation device 30 reduces the computing resource footprint of the inverse design techniques of this disclosure, while improving data precision by way of the low-loss or potentially lossless reconstruction provided by VAEs.

According to some implementations of the techniques of this disclosure, training model 46A represents an adversarial learning-based model that uses two or more neural networks, such as a generative adversarial network (GAN). In instances in which training model 46A represents a GAN, training model 46A may include two neural networks, namely, a generator network and a discriminator network. In GAN-based implementations, training model 46A may represent any of various types of GANs, such as a deep convolutional generational adversarial network (DCGAN), a Wasserstein generational adversarial network (Wasserstein GAN), a PixelGAN, a CycleGAN, or any other type of GAN. In some GAN-based implementations of training model 46A, the generator network may represent a U-Net. In some GAN-based implementations of training model 46A, the generator network and/or the discriminator network may represent a respective autoencoder network.

Training unit 42A may perform training and retraining operations on training model 46A using training data pairs 44B until training model 46A achieves convergence. Upon detecting that training model 46A has achieved convergence, training unit 42A may output trained model 46B and store trained model 46B to AI/ML models 46. In the case of GAN-based implementations, training model 46A may output the trained generator network of the GAN as trained model 46B. In the case of ANN-based implementations and VAE-based implementations, trained model 46B may represent a combination of an encoder network and a decoder network with training-generated encode weights and training-generated decode weights.

Design unit 42B may place trained model 46B in execution phase 16 to run trained model 46B. In various use-case scenarios of this disclosure, design unit 42B may provide one or more data points of intended performance metrics 44D to trained model 46B as execution-phase inputs. That is, design unit 42B may implement inverse design-based aspects of this disclosure by providing one or more of intended performance metrics 44D as a performance goal, minimum performance requirement, or other type of aspired-for performance indication as an input to trained model 46B during execution phase 16. In turn, trained model 46B may conclude at least one pass of execution phase 16 by outputting a passive structure design. In this manner, design unit 42B implements the inverse design techniques of this disclosure to run trained model 46B by providing a portion of intended performance metrics 44D as an input and obtaining a passive structure design that trained model 46B generates using the input portion of intended performance metrics 44D as a performance guideline for the corresponding passive structure.

In some examples, design unit 42B may store the passive structure design obtained from execution phase 16 of trained model 46B to output passive structure designs 44E. In some examples, deployment unit 42C may invoke I/O interface 33 to output the passive structure design obtained from execution phase 16 of trained model 46B to an external device, such as to one or more of remote devices 34 via communications link 38. In some examples, design unit 42B may save the passive structure design obtained from trained model 46B to output passive structure designs 44E in combination with deployment unit 42C outputting the passive structure design obtained from trained model 46B to the external device(s) using I/O interface 33.

In some examples, deployment unit 42C may invoke I/O interface 33 to signal data representing one or more pre-saved passive structure designs of output passive structure designs 44E over communications link 38. In these examples, passive structure generation device 30 communicates, to one or more external devices, passive structure designs that were previously generated by trained model 46A using certain parameters of intended performance metrics 44D.

For instance, deployment unit 42C may select designs of particular output passive structure designs 44E that were generated using those of intended performance metrics 44D that match or are comparable to certain intended performance parameters received via I/O interface 33 from a user of passive structure generation device 30 or from an external device that is communicatively coupled to passive structure generation device 30 over communications link 38. In this way, deployment unit 42C may implement techniques of this disclosure to enable passive structure generation device 30 to provide previously generated passive structure designs in response to performance parameter-based requests received from users and/or external device(s).

In some examples, deployment unit 42C may invoke I/O interface 33 to deploy trained model 46B to external devices, such as by signaling trained model 46B to remote devices 34 over communications link 38. In some examples, deployment unit 42C may invoke I/O interface 33 to save a copy of trained model 46B to removable storage device 52. Removable storage device 52 may represent any type of non-volatile storage media, such as an external hard drive or solid-state drive (SSD), a USB flash drive, a CD, or the like. In these examples, deployment unit 42C enables other devices to run trained model 46B in execution phase 16 to generate passive structure designs according to the inverse design-based techniques of this disclosure.

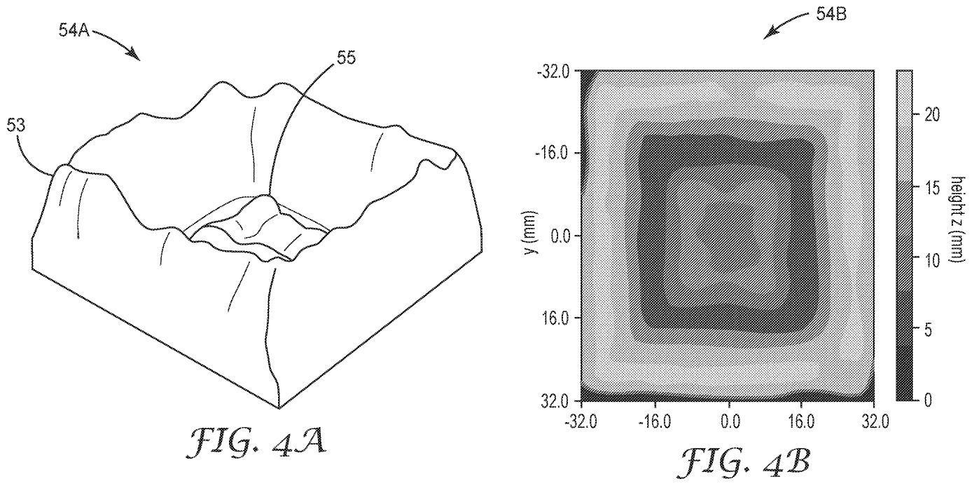

FIGS. 4A & 4B illustrate a three-dimensional representation 54A and a two-dimensional representation 54B, respectively, of a dielectric lens generated by a GAN-based implementation of trained model 46B when run in execution phase 16. That is, in the use case scenario of FIGS. 4A and 4B, trained model 46B represents an adversarially trained generator network that training unit 42A determines to have achieved convergence. Trained model 46B implements inverse design techniques of this disclosure to generate the dielectric lens design shown in FIGS. 4A & 4B. Three-dimensional representation 54A of FIG. 4A illustrates two distinct protuberance regions, namely, collar 53 and island 55. The heights (or magnitude of protuberance) of collar 53 and island 55 are shown by way of relation to the base of the dielectric lens in two-dimensional representation 54B.

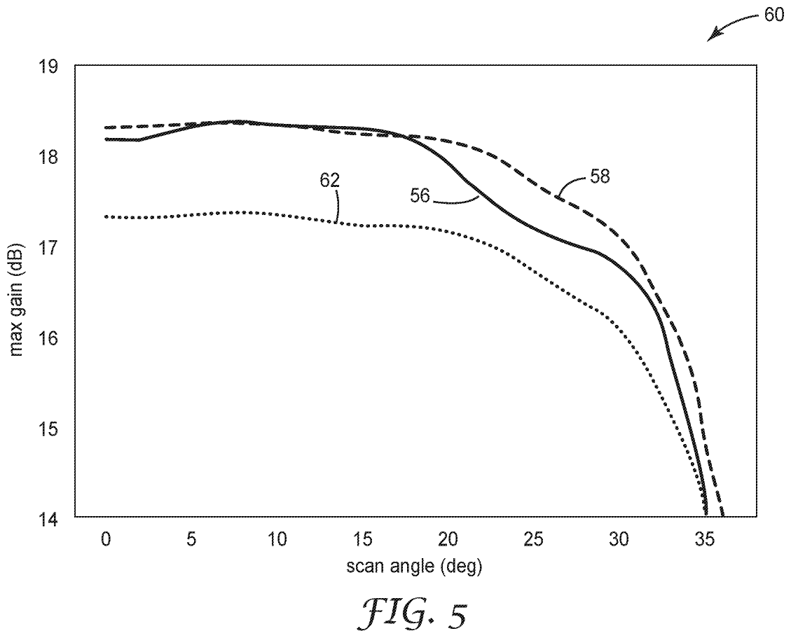

Trained model 46B takes, as input for execution phase 16, a portion of intended performance metrics 44D, and generates the illustrated lens design to provide the inputted portion of intended performance metrics 44D when a corresponding lens is incorporated into a phased antenna array. In the particular case of FIGS. 4A & 4B, as well as in the case of FIG. 5 which is described below, the input portion of intended performance metrics 44D indicate a desired 1 dB increase in gain at the boresight (zero-degree) scan angle.

FIG. 5 is a graph 60 illustrating the gain values provided by a phased antenna array that incorporates dielectric lenses that conform to the GAN-generated designs shown in FIGS. 4A & 4B. The results illustrated in FIG. 5 are generated using modeling and simulation techniques with respect to one of the lens designs generated by trained model 46B. The gain values provided by the generated lens design (according to the modeling & simulation) are shown by way of modeled gain 56. Intended gain 58 plots the gain values specified in the portion of intended performance metrics 44D that were provided to trained model 46B as input for execution phase 16.

Control line 62 illustrates the gain provided by a phased antenna array that is not equipped with the dielectric lens designed according to any of output passive structure designs 44E. As shown in graph 60, modeled gain 56 (provided by a phased antenna array equipped with dielectric lenses conforming to one of output passive structures 44E), when compared to control line 62 (which illustrates the gain provided by an antenna array that is not equipped with the dielectric lens described above), provides, on average, a 0.96 dB increase in the scan angle range of [0, 20] degrees, and, on average, 0.77 dB increase over a scan angle range of [0, 30] degrees.

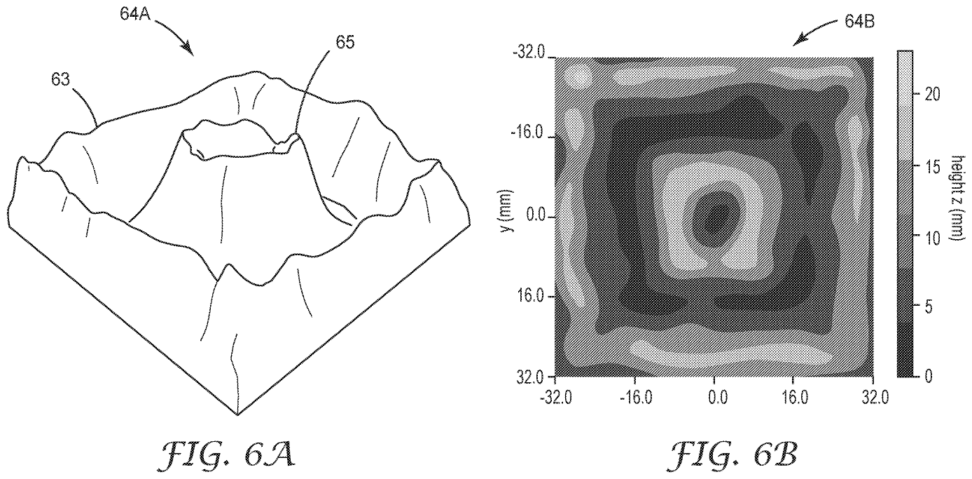

FIGS. 6A & 6B illustrate a three-dimensional representation 64A and a two-dimensional representation 64B, respectively, of a dielectric lens generated by a GAN-based implementation of trained model 46B when run in execution phase 16. Trained model 46B implements inverse design techniques of this disclosure to generate the dielectric lens design shown in FIGS. 6A & 6B, based on an input parameter of intended performance metrics 44B corresponding to a desired 2 dB increase in gain at the boresight (zero-degree) scan angle. Three-dimensional representation 64A of FIG. 6A illustrates two distinct protuberance regions, namely, collar 63 and island 65. The heights (or magnitude of protuberance) of collar 63 and island 65 are shown by way of relation to the base of the dielectric lens in two-dimensional representation 64B.

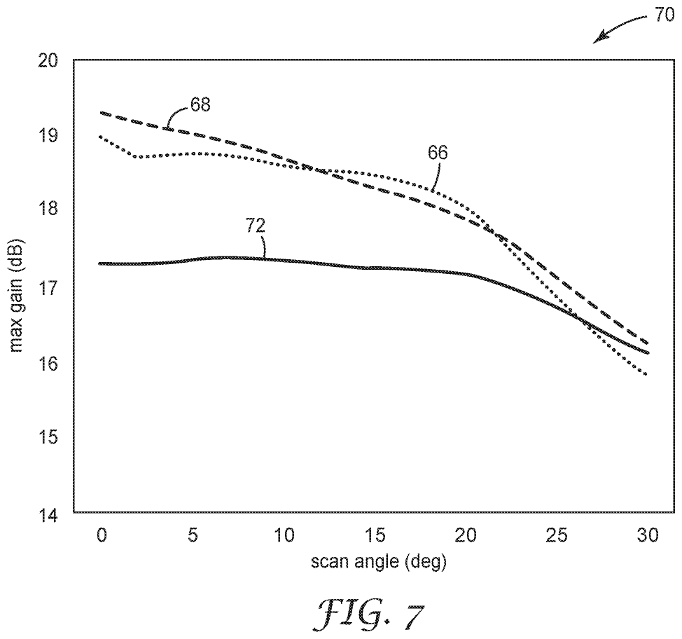

FIG. 7 is a graph 70 illustrating the gain values provided by a phased antenna array that incorporates dielectric lenses that conform to the GAN-generated designs shown in FIGS. 6A & 6B. The results illustrated in FIG. 7 are generated using modeling and simulation techniques with respect to one of the lens designs generated by trained model 46B. The gain values provided by the generated lens design (according to the modeling & simulation) are shown by way of modeled gain 66. Intended gain 68 plots the gain values specified in the portion of intended performance metrics 44D that were provided to trained model 46B as input for execution phase 16.

Control line 72 illustrates the gain provided by a phased antenna array that is not equipped with the dielectric lens designed according to any of output passive structure designs 44E. As shown in graph 70, the observed gain tapers off as the scan angle increases from zero degrees at boresight.

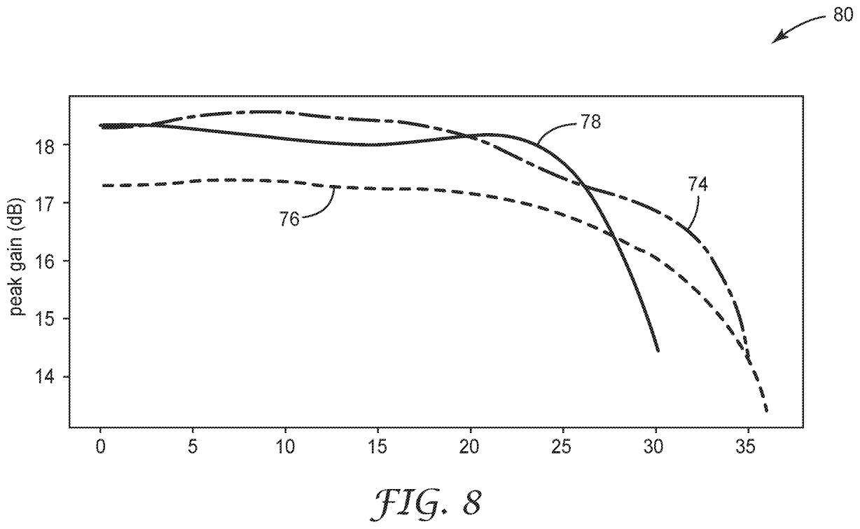

FIG. 8 is a graph 80 showing the increase in peak gain (or max gain) provided by phased antenna arrays equipped with the inverse-designed dielectric lenses of this disclosure in comparison to the peak gain provided by other phased antenna arrays. Inverse design gain 74 plots the peak gain provided by a phased antenna array that incorporates dielectric lenses that are formed according to the inverse design techniques of this disclosure (e.g., as generated by trained model 46B during execution phase 16). As shown in FIG. 8, inverse design gain 74 is a relatively steady value which does not taper off significantly until the scan angle moves significantly far from boresight. In comparison, control line 76 plots the peak gain provided by a phased antenna array that is not equipped with any additional passive structures.

Control line 76 follows a similar trajectory in comparison to inverse design gain 74, but provides a significant and consistently lower peak gain beginning at boresight and continuing through the widest scan angle. Hemispheric lens gain 78 plots the peak gain provided by a phased antenna array equipped with hemispheric lenses. Hemispheric lens gain 78 tapers off more precipitously and beginning at a significantly narrower scan angle than inverse design gain 74 or control line 76. As such, graph 80 shows that dielectric lenses designed according to the inverse design techniques of this disclosure improve the performance (in terms of peak gain) of phased antenna arrays into which they are incorporated, and provide a superior performance improvement (in terms of peak gain) when compared to phased antenna arrays equipped with other types of passive structures.

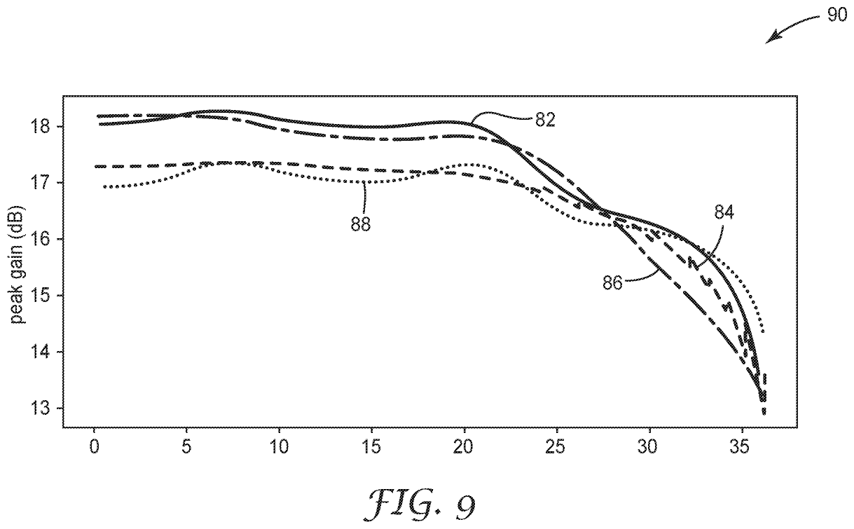

FIG. 9 is a graph 90 comparing the increase in peak gain (or max gain) provided by phased antenna arrays equipped with modified and unmodified versions of the inverse-designed dielectric lenses of this disclosure and by a phased antenna array that is not augmented with any dielectric lens infrastructure. Full lens gain line 82 plots the peak gain provided by a phased antenna array that incorporates dielectric lenses that are formed according to the inverse design techniques of this disclosure (e.g., as generated by trained model 46B during execution phase 16) as the scan angle moves away from boresight (i.e., starting at zero and increasing along the x-axis of graph 90).

Control line 84 plots the peak gain provided by a phased antenna array that is not augmented with any dielectric lens infrastructure. Island-only lens line 86 plots the peak gain provided by a phased antenna array that is augmented with a modified version of the dielectric lenses that correspond to full lens gain line 82. In the case of island-only lens line 86, the phased antenna array is equipped with dielectric lenses in which the collar (e.g., collar 53 or collar 63) is removed and the island (e.g., island 55 or island 65) is the only remaining protuberance.

Collar-only lens line 88 plots the peak gain provided by a phased antenna array that is augmented with another modified version of the dielectric lenses that correspond to full lens gain line 82. In the case of island-only lens line 86, the phased antenna array is equipped with dielectric lenses in which the collar island (e.g., island 55 or island 65) is removed and the (e.g., collar 53 or collar 63) is the only remaining protuberance.

By way of comparison to the performance plotted by control line 84, island-only lens line 86 shows that island 55/65 improves peak gain at boresight, and collar-only lens line 88 shows that collar 53/63 improves peak gain as the scan angle sweeps away from the zero-degree angle at boresight. As such, the combination of improvement at boresight and with widening scan angles shown by full lens gain line 82 illustrates that the inverse-designed dielectric lenses of this disclosure, including both collar 53/63 and island 55/65 provides an overall peak grain improvement at all scan angles, as shown by way of comparison to control line 84.

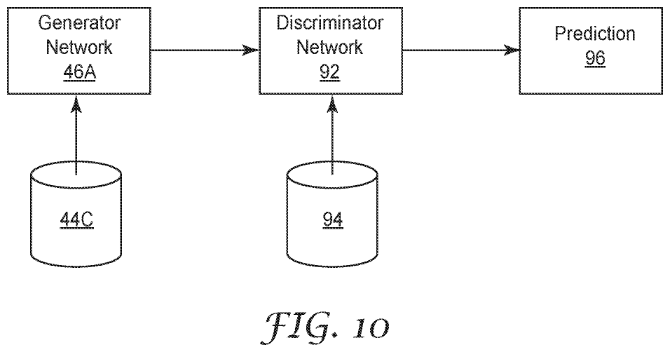

FIG. 10 is a block diagram illustrating aspects of training phase 14 with respect to training model 46A. One or more of training data pairs 44C are provided to training model 46A (illustrated in FIG. 10 as “generator network 46A”) as part of training phase 14. Discriminator network 92 is trained using one or more engineered passive structure designs 94. Engineered passive structure designs 94 represent dielectric lens designs that, in simulations or field tests, yielded significant performance improvements when integrated into phased antenna arrays. As such, engineered passive structure designs 94 can be viewed as ground truth data that is used to train the discriminator network of a GAN, which in this case is represented by discriminator network 92.

Discriminator network 92 performs adversarial training with respect to generator network 46A by outputting prediction 96. Each of generator network 46A and discriminator network 92 may represent a deep neural network. Prediction 96 represents a probability value indicating whether or not the particular one of output passive structure designs 44E output by generator network 46A in a training iteration will yield the portions of intended performance metrics 44D when integrated into a phased antenna array. Iterative passes of training phase 14 improve the data precision delivered by generator network 46A, and in some instances, improve the prediction accuracy delivered by discriminator network 92.

After a number of iterative runs of training phase 14, and based on the values of prediction 96 output by discriminator network 92, training unit 42A may determine that generator network 46A has achieved convergence. At this juncture, training unit 42A may discard discriminator network 92, and recharacterize generator network 46A as trained model 46B. The inverse design aspects of this disclosure are represented by the functionalities described with respect to generator network 46A (whether during training or post-convergence), because generator network 46A outputs dielectric lens designs based on intended performance information.

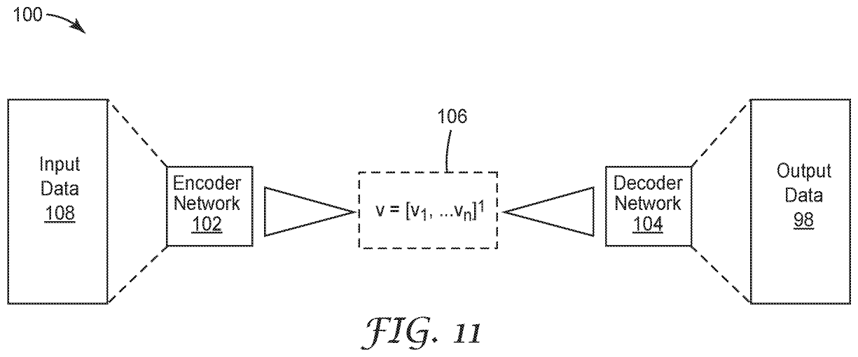

FIG. 11 is a block diagram illustrating an example of an autoencoder neural network (ANN)-based architecture of training model 46A and trained model 46B. ANN 100 includes an encoder network 102 and a decoder network 104. According to some implementations, each of encoder network 102 and decoder network 104 represents a separate neural network. Particularly in cases in which they are trained in concert, encoder network 102 and decoder network 104 may arrive at efficient ways to encode a large set of diverse images into a relatively small (n-dimensional) vector space, which is shown in FIG. 11 by way of latent space representation 106.

ANN-driven inverse design techniques of this disclosure, by exploring representations in the latent space through one or more of perturbative, interpolative, or extrapolative approaches, may generate custom passive structure designs that improve the performance of phased antenna arrays into which they are integrated. Some techniques of this disclosure leverage these attributes of ANNs to implement inverse design generation and optimization of passive structure designs.

Encoder network 102 receives input data 108. Encoder network 102 implements dimensionality reduction and other processing operations on input data 108, to form latent space representation 106. Decoder network 104 takes latent space representation 106 as input, and reconstructs latent space representation 106 as closely as possible to input data 108, to form output data 98. In a scenario of ideal or perfect performance of ANN 100, output data 98 would match input data 108 exactly. In other words, in an optimal scenario, decoder network 104 would reconstruct latent space representation losslessly. In use case scenarios that are suboptimal, output data 98 differs from input data 108 by a delta referred to as “loss” or “reconstruction loss.” The accuracy/precision of the reconstruction of output data 98 in comparison to input data 108 is expressed by a “reconstruction quality function.”

Encoder network 102 and/or decoder network 104 may include, be, or be part of multiple classes of predictive deep learning or machine learning models which work in concert. As part of training phase 14, training unit 42A may generate a dataset including several (e.g., in the order of thousands of) candidate dielectric lens designs. One of the goals of training phase 14 is to train ANN 100 to learn to generate latent space representation 106 in a way that minimizes loss in terms of the full lens reconstruction represented in output 98. Training unit 42A attempts to minimize the loss through the training of both encoder network 102 and decoder network 104.

With each iteration of training phase 14, ANN 100 improves in its capability to reconstruct output passive structure designs 44E in the design space (which represents output data 98) from input data 108 after passing through the n-dimensional latent space representation 106, which acts as a bottleneck in the inverse design process. Training unit 42A may calculate a loss function comparing output data 98 (the form of one of output passive structure designs 44E) to the original passive structure design of input data 108. Training unit 42A may express these losses as any type of relevant loss function, including, but not limited to, entropy, L1, L2, cosine similarity, or variants thereof.

Training unit 42A may use a derivative (e.g., a first derivative) of the loss function with respect to model parameters to improve the model parameters using any of relevant gradient-based or gradient-free optimization techniques such as SGD, ADAM, ADAGRAD, RMSprop, BFGS, or others. Training unit 42A may iterate these steps as part of training phase 14 until 42A the first-occurring event of resource exhaustion or ANN 100 achieving convergence. Training unit 42A may draw on various types of computational resources to implement training phase 14, such as one or more of cloud-based computational resources, or various components of processing circuitry 31 (e.g., CPU hardware, GPU hardware, etc.) in order to improve data precision with respect to execution phase 16.

After training unit 42A concludes training phase 14, design unit 42B may execute ANN 100 (which now represents trained model 46B) or deployment unit 42DC may deploy ANN 100 (which now represents trained model 46B) to another device. In execution phase 16, ANN 100 may generate instances of latent space representation 106 for one or multiple of passive structure designs 44E. Design unit 42B or a remote device performing execution phase 16 may perturb and decode a single instance of latent space representation 106 to form one or more of output passive structure designs 44E that are modified versions of a starting point regularly shaped lens. Design unit 42B or a remote device performing execution phase 16 may interpolate/extrapolate and decode multiple instances of latent space representation 106 to combine various features extracted from different dielectric lens designs to form hybridized dielectric lens designs as part of output passive structure designs 44E.

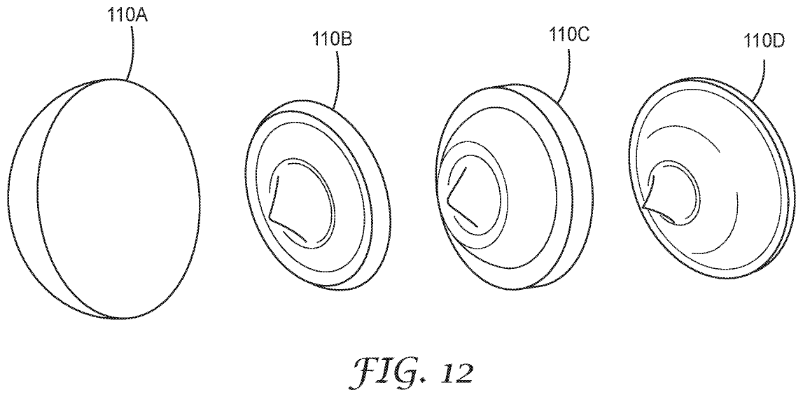

FIG. 12 illustrates examples of dielectric lens designs generated by an ANN-based implementation of trained model 46B. In execution phase 16, an ANN-based implementation of trained model 46B may take, as an execution phase input, hemispheric lens design 110A. hemispheric lens design 110A may represent an engineered design. The ANN-based implementation of trained model 46B may randomly perturb and decode a single instance of latent space representation 106 to yield irregular lens shapes 110B, 110C, and 110D. Each of irregular lens shapes 110B, 110C, and 110D represents a variation derived from hemispheric lens shape 110A, which the ANN-based implementation of trained model 46B may form via perturbation and decoding based on one or more of performance metrics 44D.

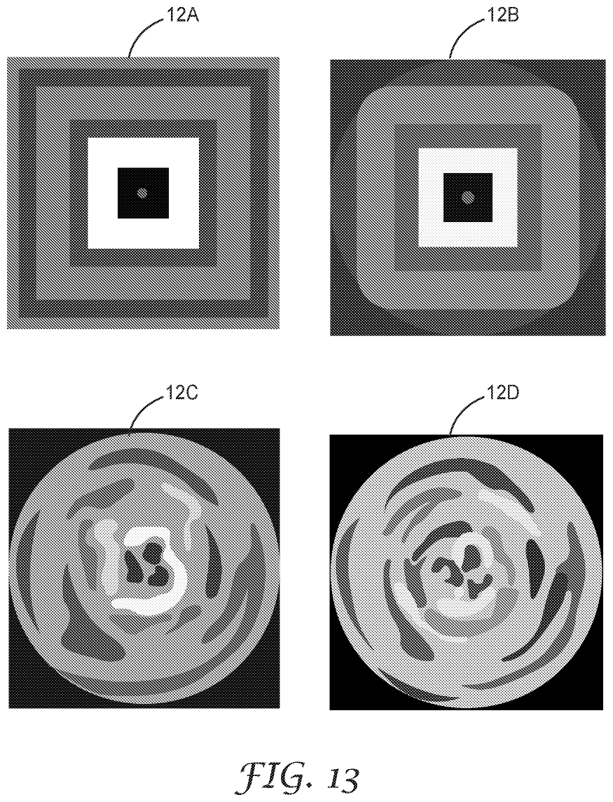

FIG. 13 illustrates top-level views of examples of dielectric lens designs generated by an ANN-based implementation of trained model 46B. In execution phase 16, an ANN-based implementation of trained model 46B may take, as execution phase inputs, starting lens designs 112A and 112D. Using starting lens designs 112A and 112D and one or more of performance metrics 44D as execution phase inputs, the ANN-based implementation of trained model 46B may interpolate across multiple instances of latent space representation 106 (e.g., respective n-dimension representations of each of starting lens designs 112A and 112D) to provide hybridized lens designs 112B and 112C. The ANN-based implementation of trained model 46B may offer additional hybridized or intermediate designs as part of providing a smooth transition from starting lens design 112A to starting lens design 112D or vice versa.

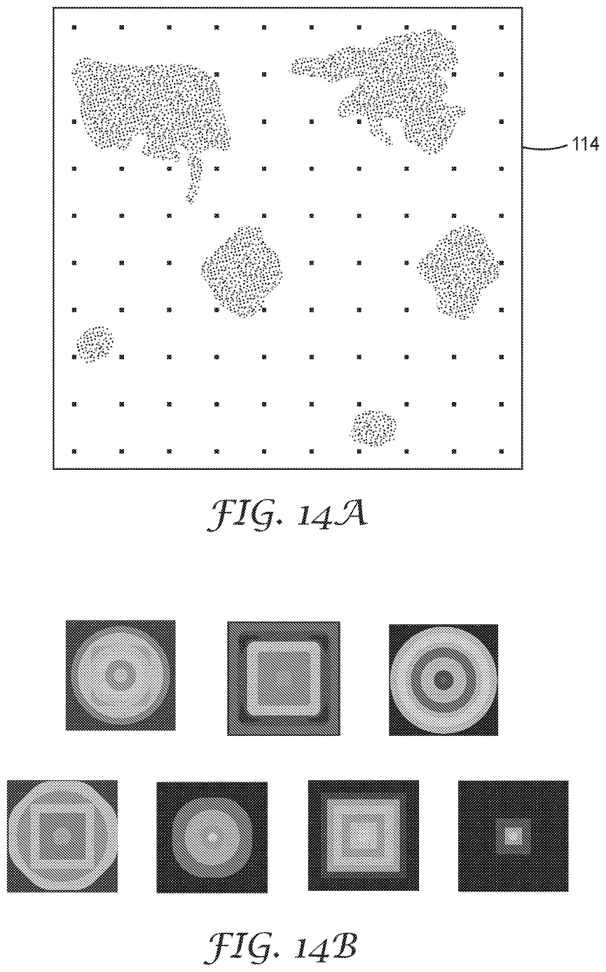

FIG. 14A is a scatterplot 114 that clusters fully encoded instances of latent space representation 106 for various lens designs. Scatterplot 114 represents the clustering of fully encoded latent space representations for 60,000 unique lens designs. Scatterplot 114 includes six distinct clusters, each representing a respective shape design family. FIG. 14B is a conceptual diagram illustrating top views of a selection of lens designs represented in FIG. 14A. FIG. 14B illustrates a sampling of lens designs across latent space representation 106, demonstrating a new-found diversity of lens shape options yielded by the ANN-based implementation of trained model 46B.

The inverse design techniques for dielectric lenses provide various technical improvements in the technical field of phased antenna array construction. As one example, the inverse design techniques of this disclosure reduce the time and resources that would otherwise be expended in arriving at a dielectric lens design that is optimized for a particular use case. The time otherwise required to iterate through the traditional design optimization process is generally in the order of a few years. In contrast, the inverse design techniques of this disclosure can be viewed as a series of three phases, namely, data collection, training phase 14, and deployment.

The time taken for the data collection depends on the application, and can be as low as in the order of minutes, ranging to the order of a few months. The time for training in many cases is in the order of hours, and may vary based on the neural network (e.g., ANN) architecture. The time for deploying the generated designs (e.g., output passive structure designs 44E) is in the order of seconds. As such, overall, the inverse design techniques of this disclosure reduce the time taken for dielectric lens design generation and deployment from several years down to, at most, a few months.

As another example of a technical improvement provided by the inverse design techniques of this disclosure, the inverse design techniques of this disclosure provide custom designs that are scenario-suited for the phased antenna arrays into which they are integrated. Various dielectric lens designs generated by trained model 46B (e.g., those shown in FIGS. displayed in FIGS. 4A, 4B, 6A, 6B, 12, and 13) do not conform to the regular geometries. Instead, the irregular surface curvatures and features lie outside the conventional engineering design paradigms, and represent irregularly shaped lenses generated using the inverse design techniques of this disclosure. As another example of a technical improvement provided by the systems of this disclosure, the neural network (e.g., GAN, ANN, etc.) architectures of this disclosure tend in favor of achieving convergence for locally optimized designs in finite, while traditional (e.g., Edisonian) design processes do not tend towards this type of convergence in many scenarios.

FIG. 15 illustrates results of GAN-based inverse design optimization techniques of this disclosure. Passive structure generation device 30 may leverage GAN-based functionalities for the purpose of design optimization to generate one or more of the results shown in FIG. 15. While the GAN-based inverse design optimization techniques of this disclosure are described primarily in the context of inverse design optimization of dielectric lenses as an example, it will be appreciated that the inverse design optimization techniques of this disclosure can be used in other application domains as well. Passive structure generation device 30 may implement GAN-based inverse design optimization techniques of this disclosure to start from a stock lens design to form an optimal lens design (as determined using intended performance metrics 44D), or a closest available lens design to the optimal lens design.

In various inverse design optimization-based implementations of AI/ML models 46, the generator network and discriminator network of training model 46A may be any of multiple classes of predictive deep learning or machine learning models. For instance, the generator network may comprise an encoder and decoder network of an autoencoder or a VAE. In other examples, the generator network may be a U-NET or may be composed of multiple U-NETs chained in series or connected in parallel. In some examples, the decoder of such a generator network may be a locked decoder from an autoencoder pretrained in an unsupervised method, or a beta-VAE.

The discriminator network of training model 46A may also be any member of a set of deep learning or machine learning models, such as a deep convolutional neural network. Various examples of GAN architectures in accordance with the inverse design optimization techniques of this disclosure include deep convolutional GANs (DCGANs), Wasserstein GAN (WGANs), PixelGANs, CycleGANs, or any variants thereof. In some examples of the techniques of this disclosure passive structure generation device 30 may use variational auto encoders (VAEs) in a standalone way or in combination with a GAN to perform the inverse design optimization techniques of this disclosure. In some examples, residual connections and/or attention mechanisms may be incorporated into the generator and/or discriminator networks of a GAN represented by training model 46A.

Training unit 42A may train the GAN-based inverse design optimizer implementation of training model 46A using training data pairs 44C. For example, training unit 42A may train the generator to learn the inverse mapping from the intended performance portions of training pairs 44C to a corresponding optimized lens design. In each iteration of training phase 14, the generator network generates an optimized lens design given a particular portion of intended performance metrics 44D as input (as part of one or more of training pairs 44C). Training unit 42A may calculate a loss function by comparing the optimized design and the engineered design as well as comparing the prediction of the discriminator given the optimized design.

These operations are part of a conditional implementation of the GAN-based optimizer of this disclosure, in which the optimized design is conditioned on having similarities or shared characteristics with (or characteristics derived from those of) the engineered design. In each iteration of training phase 14 of the discriminator, training unit 42A may calculate the loss function by comparing the prediction given to the optimized design against an all-zeros value and comparing the prediction given to the engineered design against an all-ones value. To calculate the losses (as a result of the above-described comparisons), training unit 42A may use any relevant loss function (e.g., cross entropy, L1, L2, cosine similarity, etc.) or variants thereof.

Training unit 42A may use the derivative of the loss function with respect to model parameters to improve or further refine the model parameters using any of relevant gradient-based or gradient-free optimization techniques (e.g., SGD, ADAM, ADAGRAD, RMSprop, BFGS, etc.). Training unit 42A may iterate these steps until detecting convergence of the generator network or until determining a state of resource exhaustion, whichever occurs first. After the conclusion of training phase 14, design unit 42B or a remote device may place the trained generator network (represented by trained model 42B) in execution phase 16 to output one or multiple optimized lens designs corresponding to those of intended performance metrics 44D that are provided as execution phase input. In various use case scenarios, design unit 42B or the remote device may either output the optimized in one prediction iteration (e.g., by outputting only one desirable design which meets or exceeds the intended performance metrics 44D provided as execution phase input), or may output multiple optimized designs in different iterations of execution phase 16. In the latter scenario, design unit 42B or the remote device may postprocess (e.g. by filtering the multiple designs) to identify the best performing design(s).

Hemispherical lens design 116 is an engineered design, such as a lens design manually generated by a research engineer. Irregularly shaped lens designs 118, 120, and 122 represent optimized lens designs that design unit 42B or a remote device executing trained model 46B may output, using hemispherical lens design 116 as a starting point). Each of irregularly shaped lens designs 118, 120, and 122 represents an optimized design that trained model 46B forms from hemispherical lens design 116 (whether in a single step or through a chain of optimization steps) based on a portion of intended performance metrics 44D provided as an execution phase input. By taking intended performance metrics 44D and generating one or more of irregularly shaped lens designs 118, 120, or 122 as output, trained model 46B performs the inverse design optimization techniques of this disclosure.

According to some aspects of this disclosure, training unit 42A may train training model 46A to improve the fidelity of the lens designs that are generated and/or optimized using various deep learning methods described above. As used herein, the term “fidelity” refers to a metric of similarity between the generated/optimized lens design that is output by training model 46A or trained model 46B and the conventionally engineered lens design(s) that are treated as ground truth lens design(s).

In one example, training unit 42A may first train an autoencoder network in an unsupervised manner. In turn, training unit 42A may use the pretrained decoder of the autoencoder as a locked decoder in the generator of the GAN represented by training model 46A. In this way, training unit 42A may essentially use a pretrained decoder with locked weights as part of the generator network of the GAN represented by training model 46A. In this way, training unit 42A may reduce the complexity of the learning task for the generator network. Rather than requiring the generator network to learn mappings from intended performance metrics 44D to a full-blown lens design, training unit 42A trains the generator network to learn a mapping from intended performance metrics 44D to a featurized representation of the lens design. Generally, the featurized representation is of a dimensionality that is one or more orders of magnitude lower than the dimensionality of a full representation of the same lens design.

In experiments, GAN-trained generator-based implementations of trained model 46B improves the fidelity of output passive structure designs 44E. Again, the improved fidelity of output passive structure designs 44E indicates that output passive structure designs 44E more closely resemble the engineered lens designs that are used as ground truth designs. These implementations of trained model 46B provide the technical improvement of imposing constraints (such as manufacturability constraints) on output passive structure designs 44E.

In some examples, the generator network of the GAN-based implementations of training model 46A and trained model 46B is a U-NET. The U-NET may be composed of an encoder and a decoder (with the encoder and decoder each being composed of multiple blocks of convolutions, nonlinearities, down sampling or up sampling operations, and transpose convolutions). In some implementations that are consistent with aspects of this disclosure, the U-NET representing the generator network may not include residual or skip connections (e.g., res-net type connections), while in other implementations that are consistent with aspects of this disclosure, the U-NET representing the generator network may not include residual or skip connections (e.g., res-net type connections).

At a first stage, training unit 42A may train a first U-NET using a dataset composed of designs. Training unit 42A may pass in the design, causing the U-NET to an encoded representation and decode the encoded representation to form a resulting output. Training unit 42A may compare the resulting output of the U-NET to the original design. At this stage, the first U-NET learns identity mapping, and encodes the design to a latent space representation. In turn, training unit 42A trains the decoder portion of the first U-NET to learn the mapping from the latent representation to the design.

At a second stage, as a benchmark for comparison, training unit 42A may train a second U-NET to learn a mapping from performance to design. As such, training unit 42A may train the second U-NET using pairs or two-tuples having a (performance, design) structure. At a third stage, passive structure generation device 30 may construct a third U-NET using a similar architecture to the first two U-NETs, with the decoder of the first UNET in immutable (or unmodifiable) form being used as the decoder in the third U-NET. Training unit 42A may train the third U-NET using (performance, design) two-tuples.

In some examples, passive structure generation device 30 may maintain corresponding or sometimes even identical architectures and training hyperparameters (e.g., learning rate, loss function, number of epochs, training set and validation set sizes, etc.) for all three U-NETs described above, in order to keep experiments as comparable as possible. A non-limiting example of a loss function that training unit 42A may use is binary cross entropy, such as in cases in which the synthetic dataset is composed of images with binary pixel values as lens designs. In some examples consistent with aspects of this disclosure, training unit 42A may implement the pre-trained decoder in a mutable (or modifiable) form. In these examples, training unit 42A provides the pre-trained decoder a “warm-start” with respect to the third U-NET, in that the weights of the decoder of the third U-NET are not initiated randomly, but instead, set to the weights of the decoder of the first U-NET.

Experimental results indicated that pre-training the decoder reduces the training and validation loss values and produced higher fidelity with respect to the lens designs generated during execution phase 16. These experimental results reflected the fidelity of the raw outputs from a sigmoid layer at the end of the U-NET chain, even without the benefits of thresholding or other post-processing. While the experimental results of the U-NET chain implementation of this disclosure targeted higher-fidelity lens designs for a particular application (in this case, for integration into 5G phased antenna arrays), it will be appreciated that the U-NET chain-based techniques of this disclosure can be applied to improve the fidelity of inverse automated designs generated for other end-uses as well.

Some aspects of this disclosure are directed to systems and techniques for generating the dataset(s) represented by training data pairs 44C. In these examples, passive structure generation device 30 or another device configured according to these aspects of this disclosure may generate the labeled dataset represented by training data pairs 44C that enables the supervised learning-based training of a deep learning model (e.g. a GAN) represented by training model 46A. Again, the labeled dataset represented by training data pairs 44C comprises 2-tuples having a (performance, design) structure.

A device configured to implement the labeled dataset generation techniques of this disclosure may use EM simulation or measurements to characterize the performance of a finite set of lens designs. In some examples, the device may select a pair of these lens designs (hereinafter, the “parent designs”) out of the finite set and interpolate the two parent designs to generate one or more “offspring designs.” For instance, the device may use an autoencoder pretrained in an unsupervised manner to interpolate between the two parent designs to generate the offspring design(s).

The device may simulate/estimate the performance of the offspring designs using an interpolation of the performance attributed to the parent designs. In this way, the device may generate new 2-tuples having an (offspring design, estimated performance) structure, which may be used to populate training pairs 44C. The device may select two parent designs out of a set of N parent designs in a combinatorial number of ways and generate tens of interpolated offspring designs from each respective pair of parent designs. In this way, devices of this disclosure may provide the technical improvement of increasing dataset size (also referred to as “data augmentation”) with respect to training data pairs 44C.

By providing data augmentation with respect to training data pairs 44C, devices of this disclosure provide the technical improvement of improved data precision with respect to the prediction functionalities of trained model 46B. Among the technical improvements provided by these techniques of this disclosure is improved data precision by way of performance prediction/estimation. By predicting an estimated performance of the offspring lens designs, these techniques of this disclosure provide data augmentation with respect to a synthetic dataset used to generate training data pairs 44C, thereby improving the precision of training phase 14 with respect to training module 46A.

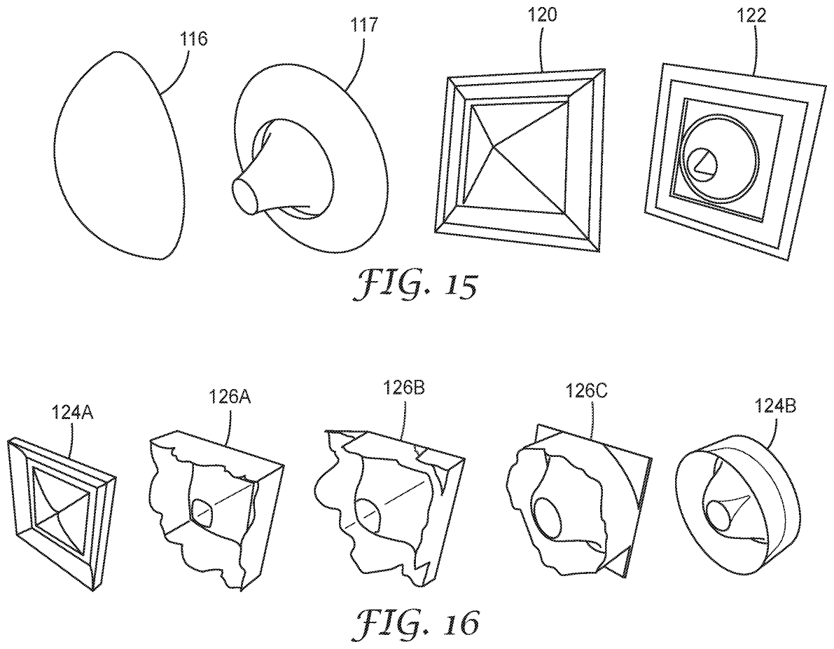

FIG. 16 illustrates an example of interpolated lens designs generated as part of the labeled dataset generation techniques of this disclosure. In the example of FIG. 16, parent designs 124A and 124B represent two different engineered designs that a neural network (e.g., an ANN) of this disclosure may use as bookended starting points in the interpolation process. Systems of this disclosure may execute a simulation technique (e.g. an EM solver) to simulate performances. The labeled dataset-generating neural network of this disclosure may interpolate between parent designs 124 to generate a number of hybridized lens designs, three of which are illustrated in FIG. 16 as offspring designs 126A-C.

In some examples, the interpolation is based on a hypothesis that parent designs 124 represent an upper bound and a lower bound in terms of lens performance, and that the performance of each of offspring designs 126 (being interpolations of the pair of parent designs 124) can be estimated by interpolating the performances of parent designs 124 by using the same weighted average formula used to generate each respective offspring design 126. This hypothesis can be expressed in the form of equations (1) and (2) below:

$$if$$

$$lens\_offspring = alpha * lens\_parent \_first + ( 1 - alpha ) * lens\_parent \_second \qquad ( 1 )$$

$$then$$

$$perf\_offspring = alpha * perf\_parent \_first + ( 1 - alpha ) * perf\_parent \_second \qquad ( 2 )$$

where “perf” denotes performance. The respective performance estimation for each of offspring designs 126 is generated using a different value for the constant denoted by “alpha” in equation (2) above.

A course of multiple experiments confirmed the hypothesis described with respect to equations (1) and (2), in that the simulated performance of the interpolated lenses described by offspring designs 126 matched or were relatively close to the interpolated performance metrics obtained using equation (2). In one example, the performance of parent design 124A is quantified as a figure of merit (FoM) of −0.5, while the FoM for parent design 124B is 1.86. The labeled dataset-generating neural network (an ANN in this experiment) interpolated parent designs 124 to generate offspring designs 126, using a different value for “alpha” in equation (1) to generate each of offspring designs 126A, 126B, and 126C.

In one experimental example, parent designs 124 represent one pair of parent designs out of 3,240 pairs formed from 81 candidate parent lens designs. As part of this particular experiment, the labeled dataset-generating ANN of this disclosure interpolated each respective parent design pair in twenty ways, thereby producing a total of 64,800 datapoints. In contrast to existing EM modeling-based techniques, which would require over seven years to generate 64,800 datapoints, the ANN of this disclosure generated the 64,800 datapoints in less than a week.

As such, the systems of this disclosure provide the technical enhancement of data augmentation in significantly reduced time and with significantly reduced resource expenditure when compared to existing techniques. While the experiments described herein demonstrated the technical improvements (e.g. of data precision and resource footprint reduction) with respect to the particular application of synthetic lens design for 5G phased antenna arrays as a non-limiting example, it will be appreciated that the dataset augmentation techniques of this disclosure may be applicable to various other uses of inverse automated design solutions as well.

In the present detailed description of the example embodiments, reference is made to the accompanying drawings, which illustrate specific embodiments in which the invention may be practiced. The illustrated embodiments are not intended to be exhaustive of all embodiments according to the invention. It is to be understood that other embodiments may be utilized, and structural or logical changes may be made without departing from the scope of the present invention. The following detailed description, therefore, is not to be taken in a limiting sense, and the scope of the present invention is defined by the appended claims.

Unless otherwise indicated, all numbers expressing feature sizes, amounts, and physical properties used in the specification and claims are to be understood as being modified in all instances by the term “about” or “approximately” or “substantially.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a,” “an,” and “the” encompass embodiments having plural referents, unless the content clearly dictates otherwise. As used in this specification and the appended claims, the term “or” is generally employed in its sense including “and/or” unless the content clearly dictates otherwise.

It is to be recognized that depending on the example, certain acts or events of any of the methods described herein can be performed in a different sequence, may be added, merged, or left out altogether (e.g., not all described acts or events are necessary for the practice of the method). Moreover, in certain examples, acts or events may be performed concurrently, e.g., through multi-threaded processing, interrupt processing, or multiple processors, rather than sequentially.

The techniques described in this disclosure may be implemented, at least in part, in hardware, software, firmware or any combination thereof. For example, various aspects of the described techniques may be implemented within one or more processors, including one or more microprocessors, CPUs, GPUs, DSPs, application specific integrated circuits (ASICs), field programmable gate arrays (FPGAs), or any other equivalent integrated or discrete logic circuitry, as well as any combinations of such components. The term “processor” or “processing circuitry” may generally refer to any of the foregoing logic circuitry, alone or in combination with other logic circuitry, or any other equivalent circuitry. A control unit comprising hardware may also perform one or more of the techniques of this disclosure.

Such hardware, software, and firmware may be implemented within the same device or within separate devices to support the various operations and functions described in this disclosure. In addition, any of the described units, modules or components may be implemented together or separately as discrete but interoperable logic devices. Depiction of different features as modules or units is intended to highlight different functional aspects and does not necessarily imply that such modules or units must be realized by separate hardware or software components. Rather, functionality associated with one or more modules or units may be performed by separate hardware or software components or integrated within common or separate hardware or software components.

The techniques described in this disclosure may also be embodied or encoded in a computer-readable medium, such as a computer-readable storage medium, containing instructions. Instructions embedded or encoded in a computer-readable storage medium may cause a programmable processor, or other processor, to perform the method, e.g., when the instructions are executed. Computer-readable storage media may include random access memory (RAM), read only memory (ROM), programmable read only memory (PROM), erasable programmable read only memory (EPROM), electronically erasable programmable read only memory (EEPROM), flash memory, a hard disk, a CD-ROM, a floppy disk, a cassette, magnetic media, optical media, or other computer readable media.

Various examples have been described. These and other examples are within the scope of the following claims.

1. A method of generating a passive structure design, the method comprising:
receiving, by processing circuitry of a computing device, a set of performance metrics;
providing, by the processing circuitry, the set of performance metrics to a trained generator network;
receiving, by the processing circuitry, a passive structure design from the trained generator network; and
outputting, by the processing circuitry, via a communication interface, the passive structure design.

2. The method of claim 1, wherein the set of performance metrics comprises a gain for one or more predetermined scan angles.

3. The method of claim 1, further comprising:
providing, by the processing circuitry, the passive structure design to a simulator;
receiving at least one simulated performance metric from the simulator.

4. The method of claim 1, wherein the passive structure design comprises a design for an irregularly shaped lens.

5. A method of training a generator network, the method comprising:
receiving a set of training pairs, each training pair comprising a training passive structure and performance data associated with the training passive structure;
for each training pair included in the set of training pairs:
providing the corresponding performance data to the generator network;
receiving an artificial passive structure from the generator network;
providing the artificial passive structure and the passive structure included in the training pair to a discriminator network;
receiving a score from the discriminator network; and
updating, based on the score, the discriminator network and the generator network to form, respectively, a trained discriminator network and a trained generator network; and
outputting the trained generator network.

6. The method of claim 5, further comprising generating each training passive structure included in the set of training pairs using a Bayesian technique.

7. The method of claim 5, wherein the generator network and the discriminator network are included in at least one of a deep convolutional generational adversarial network (DCGAN), a Wasserstein generational adversarial network (Wasserstein GAN), a PixelGAN, or a CycleGAN.

8. The method of claim 5, wherein at least one of the generator network or the discriminator network comprises an autoencoder.

9. The method of claim 5, wherein each of the generator network and the discriminator network comprises a respective neural network.

10. The method of claim 5, wherein the generator comprises a U-Net.

11. A passive structure generation device comprising:
at least one non-transitory computer-readable storage medium having instructions stored thereon;
at least one processor coupled to the at least one non-transitory computer-readable storage medium and configured to execute the instructions to:
receive a set of performance metrics;
provide the set of performance metrics to a trained generator;
receive a passive structure from the generator; and
output the passive structure to at least one of a user interface, an external device, or the at least one non-transitory computer-readable storage medium.

12. The passive structure generation device of claim 11, wherein the set of performance metrics comprises a gain for one or more predetermined scan angles.

13. The passive structure generation device of claim 11, wherein the at least one processor is further configured to execute the instructions to:
provide the passive structure to a simulation technique;
receive at least one simulated performance metric from the simulation technique.

14. The passive structure generation device of claim 11, wherein the trained generator is previously trained by:
receiving a set of training data pairs, each training data pair comprising a training passive structure and performance data associated with the training passive structure;
for each training data pair included in the set of training data pairs:
providing the performance data to the generator;
receiving an artificial passive structure from the generator;
providing the artificial passive structure and the passive structure included in the training data pair to the discriminator;
receiving a score from the discriminator; and
updating the discriminator and the generator based on the score; and
outputting the generator as a trained generator.

15. The passive structure generation device of claim 14, wherein each training passive structure included in the set of training data pairs is generated using a Bayesian technique.

16. The passive structure generation device of claim 14, wherein the generator and the discriminator are included in at least one of a deep convolutional generational adversarial network, a Wasserstein generational adversarial network, a PixelGAN, or a CycleGAN.

17. The passive structure generation device of claim 14, wherein at least one of the generator or the discriminator comprises an autoencoder.

18. The passive structure generation device of claim 14, wherein the generator comprises a UNET.

19. The passive structure generation device of claim 11, wherein the passive structure comprises an irregularly shaped lens.

20. (canceled)
